(19) United States
(12) Patent Application Publication
(10) Pub. No.: US 2026/0146328 A1
(43) Pub. Date: May 28, 2026

(54) SHOWER HEAD AND SUBSTRATE PROCESSING APPARATUS INCLUDING THE SAME

(71) Applicant: Samsung Electronics Co., Ltd., Suwon-si (KR)

(72) Inventors: Daewee Kong, Suwon-si (KR); Taewon Lee, Suwon-si (KR)

(21) Appl. No.: 19/398,731

(22) Filed: Nov. 24, 2025

(30) Foreign Application Priority Data
Nov. 25, 2024 (KR) 10-2024-0170115
Jan. 21, 2025 (KR) 10-2025-0008983

(51) Int. Cl. C23C 16/455

(52) U.S. Cl. CPC C23C 16/45565

(57) ABSTRACT

Provided are a shower head including a first plate, an inlet pipe connected to a center of the first plate, a second plate facing the first plate, and a first step plate provided on a second surface of the second plate facing a first surface of the first plate, wherein the first surface is parallel to the second surface, the second plate includes a plurality of injection holes, the plurality of injection holes penetrate the second plate, the first step plate includes a plurality of first step holes, the plurality of first step holes penetrate the first step plate, and all of the plurality of first step holes are aligned in a vertical direction, in correspondence to the plurality of injection holes, respectively, and a substrate processing apparatus including the shower head.

### CROSS-REFERENCE TO RELATED APPLICATIONS

This application is based on and claims priority under 35 U.S.C. § 119 to Korean Patent Application Nos. 10-2024-0170115, filed on Nov. 25, 2024, and 10-2025-0008983, filed on Jan. 21, 2025, in the Korean Intellectual Property Office, the disclosures of which are incorporated by reference herein in their entirety.

### BACKGROUND

The inventive concept relates to a shower head and a substrate processing apparatus including the same.

The chemical vapor deposition (CVD) process for forming a thin film on a substrate in a process of manufacturing semiconductor devices, display devices, or the like supplies a reaction gas into a vacuum or low-pressure chamber and chemically reacts the reaction gas with the surface of the substrate in a high-temperature environment to form a thin film on the surface of the substrate. In this case, it is important to uniformly distribute the reaction gas on the substrate, and to this end, a shower head having a plurality of gas injection holes may be provided in a substrate processing apparatus.

The shower head should be configured so that the reaction gas does not cause a gas concentration deviation or a temperature distribution deviation. The distribution non-uniformity of the reaction gas may affect product quality by causing thickness deviation, film quality degradation, or crystalline non-uniformity of a thin film formed on a substrate. As the miniaturization of devices and the combination of materials are accelerated, more precise thin film formation and stable process reproducibility are required. In addition, due to the substrate processing process in a high-temperature environment, the durability of the shower head also needs to be considered. This has led to a demand for shower heads that are more durable and optimized for gas injection.

### SUMMARY

The inventive concept provides a gas shower head in which durability is ensured and gas is uniformly injected, and a substrate processing apparatus including the same.

The technical problem to be solved by the technical idea of the inventive concept is not limited to the above-mentioned problem, and other problems not mentioned may be clearly understood by those of ordinary skill in the art from the following description.

According to an aspect of the inventive concept, there is provided a gas shower head including a first plate having a first surface facing a first direction, an inlet at a center of the first plate, a second plate having a second surface facing the first surface of the first plate, and a first step plate provided on the second surface of the second plate, wherein the first surface is parallel to the second surface, the second plate includes a plurality of injection holes, the plurality of injection holes penetrate through the second plate, the first step plate includes a plurality of first step holes, the plurality of first step holes penetrate through the first step plate, and each first step hole of the plurality of first step holes is aligned in a vertical direction with a corresponding injection hole of the plurality of injection holes.

In addition, according to another aspect of the inventive concept, there is provided a gas shower head including a first plate having a first surface facing a first direction, an inlet at a center of the first plate, a second plate having a second surface facing the first surface of the first plate, and a first step plate provided on the second surface of the second plate and having a third surface facing the first surface of the first plate and a fourth surface facing the second surface of the second plate, wherein the second plate includes a plurality of injection holes, the plurality of injection holes penetrate through the second plate, each injection hole of the plurality of injection holes has the same diameter, the first step plate includes a plurality of first step holes, the plurality of first step holes penetrate through the first step plate, and each first step hole of the plurality of first step holes is aligned in the first direction with a corresponding injection hole of the plurality of injection holes, the first surface of the first plate, the second surface of the second plate, the third surface of the first step plate, and the fourth surface of the first step plate are all parallel to each other, and a center of the first step plate, a center of the second plate, and a center of the inlet pipe are all located on a virtual first center line extending in the first direction.

In addition, according to another aspect of the inventive concept, there is provided a substrate processing apparatus including a process chamber having an inner space, a gas shower head provided in one side of the inner space of the process chamber, a gas supply unit connected to the gas shower head to provide gas, and a substrate support unit provided in the inner space of the process chamber, and configured to support a substrate, wherein the gas shower head includes a first plate having a first surface, an inlet connected to a center of the first plate, a second plate having a second surface facing the first surface of the first plate, and a first step plate provided on the second surface of the second plate and having an upper surface facing the first surface of the first plate and a lower surface facing the second surface of the second plate, the first surface, the second surface, an upper surface of the first step plate, and a lower surface of the first step plate are parallel to each other, the second plate includes a plurality of injection holes, the plurality of injection holes penetrate through the second plate, the first step plate includes a plurality of first step holes, the plurality of first step holes penetrate through the first step plate, and each first step hole of the plurality of first step holes are aligned in a vertical direction with a corresponding injection hole of the plurality of injection holes, the lower surface of the first step plate is in contact with the second surface of the second plate, the diameter of the first step plate is greater than the diameter of the inlet, a first fillet is provided at the intersection of the inlet and the first surface of the first plate, the first fillet includes a fillet curved surface extending between the inlet and the first surface, and the substrate support unit includes a chuck electrode, a heater, and a plasma electrode inside the substrate support unit.

### BRIEF DESCRIPTION OF THE DRAWINGS

Embodiments will be more clearly understood from the following detailed description taken in conjunction with the accompanying drawings in which:

FIG. 1 is a cross-sectional view illustrating a substrate processing apparatus including a shower head according to embodiments;

FIG. 2A is a cross-sectional view of a shower head according to embodiments;

FIG. 2B is a cross-sectional perspective view of a shower head according to embodiments;

FIG. 2C is an enlarged cross-sectional view of a portion of a shower head according to embodiments;

FIG. 2D is an enlarged plan view of a portion of a shower head according to embodiments;

FIG. 3A is a cross-sectional view of a shower head according to embodiments;

FIG. 3B is an enlarged cross-sectional view of a portion of a shower head according to embodiments;

FIG. 3C is an enlarged plan view of a portion of a shower head according to embodiments;

FIG. 4A is an enlarged cross-sectional view of a portion of a shower head according to embodiments;

FIG. 4B is an enlarged plan view of a portion of a shower head according to embodiments;

FIG. 5A is an enlarged cross-sectional view of a portion of a shower head according to embodiments;

FIG. 5B is an enlarged plan view of a portion of a shower head according to embodiments;

FIG. 6A is an enlarged cross-sectional view of a portion of a shower head according to embodiments;

FIG. 6B is an enlarged plan view of a portion of a shower head according to embodiments;

FIG. 7A is an enlarged cross-sectional view of a portion of a shower head according to embodiments;

FIG. 7B is an enlarged plan view of a portion of a shower head according to embodiments;

FIG. 8 is an enlarged cross-sectional view of a portion of a shower head according to embodiments; and

FIG. 9 is an enlarged cross-sectional view of a portion of a shower head according to embodiments.

### DETAILED DESCRIPTION OF THE EMBODIMENTS

Hereinafter, embodiments of the technical idea of the inventive concept will be described in detail with reference to the accompanying drawings. Items described in the singular herein may be provided in plural, as can be seen, for example, in the drawings. Thus, the description of a single item that is provided in plural should be understood to be applicable to the remaining plurality of items unless context indicates otherwise.

Embodiments of the technical idea of the inventive concept are provided to more completely explain the technical idea of the inventive concept to one of ordinary skill in the art, and the following embodiments may be modified in various different forms, and the scope of the technical idea of the inventive concept is not limited to the following embodiments. Rather, these embodiments are provided to make the inventive concept more faithful and complete, and to fully convey the spirit of the inventive concept to one of ordinary skill in the art. The language of the claims should be referenced in determining the requirements of the invention. In addition, the thickness or size of each layer in the drawings may be exaggerated for convenience and clarity of explanation.

In the present specification, a first direction may refer to an X-direction, a second direction may refer to a Y-direction, and the first direction and the second direction may be perpendicular to each other. A third direction may be a Z-direction, and the third direction may be perpendicular to each of the first direction and the second direction. A horizontal plane or plane refers to an X-Y plane. A top surface of a specific object means one surface positioned in a positive third direction with respect to the specific object, and a bottom surface of the specific object means one surface positioned in a negative third direction with respect to the specific object.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

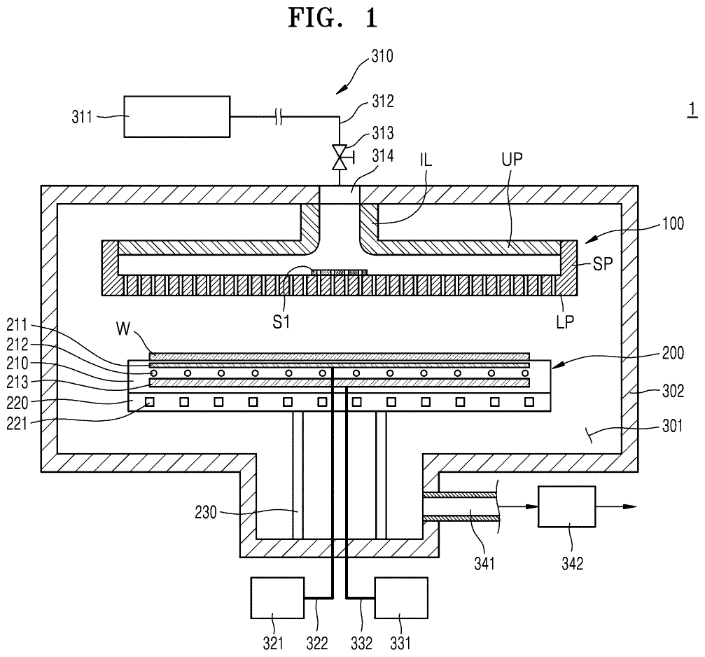

FIG. 1 is a cross-sectional view illustrating a substrate processing apparatus 1 including a gas shower head, which may be referred to as a shower head 100 according to embodiments.

Referring to FIG. 1, the substrate processing apparatus 1 according to embodiments may include a process chamber 302 having an inner space 301 for processing a substrate W within, a substrate support unit 200 arranged in the inner space 301, a gas supply unit 310 for supplying gas to the inner space 301, a direct-current (DC) power generator 321, a radio-frequency (RF) power generator 331, an exhaust port 341, and a vacuum pump 342.

The substrate processing apparatus 1 according to the present embodiments may be an apparatus for processing the substrate W using a fluid. For example, the substrate processing apparatus 1 may perform a process of forming a thin film on the substrate W. More specifically, the substrate processing apparatus 1 may perform a chemical vapor deposition (CVD) process on the substrate W. However, the inventive concept is not limited thereto, and the substrate processing apparatus 1 may be an apparatus that performs other deposition processes and/or etching processes on the substrate W. The term “substrate” W used in the present specification may refer to a silicon (Si) wafer, but is not limited thereto.

The substrate processing apparatus 1 may process a substrate using, for example, plasma. To this end, the substrate processing apparatus 1 may generate plasma in various methods. For example, the substrate processing apparatus 1 may be a capacitively coupled plasma (CCP) apparatus.

The inner space 301 of the process chamber 302 for performing a process within may be separated from an outer space external to the process chamber 302. While the process for the substrate W is in progress within the inner space 3021, the inner space 301 may be in a substantial vacuum state by the vacuum pump 342. The process chamber 302 may have a cylindrical shape, but is not limited thereto.

A gas inlet port 314 for introducing gas may be provided at a first side (e.g., an upper end) of the process chamber 302. An exhaust port 341 for exhausting reaction by-products and residual gases generated in the process may be provided on a second side (e.g., lower end) of the process chamber 302. The first side may be opposite of the second side.

The gas supply 310 may supply the process gas to the inner space 301 through the gas inlet port 314. The gas supply 310 may include gas storage 311, a gas supply line 312, and a valve 313. The gas supply line 312 may connect the gas storage 311 and the gas inlet port 314 with each other, and the process gas stored in the gas storage 311 may be supplied to the inner space 301 through the gas supply line 312 and the gas inlet port 314. A valve may be provided on the gas supply line 312, and the valve may selectively open and close the gas supply passage or adjust the flow rate of the process gas supplied to the inner space 301.

The process gas supplied through the gas inlet port 314 may be injected onto the substrate W through the shower head 100. The shower head 100 may include a first plate UP, a second plate LP, a side plate SP extending from a side of the first plate UP and coupled to the second plate LP, a gas inlet pipe IL connected to a central portion of the first plate UP and communicating with the gas inlet port 314, and a first step plate S1. A more detailed structure of the shower head 100 will be described later. The gas inlet pipe IL may provide an inlet to the shower head or be connected to an inlet of the shower head.

The shower head 100 may have a plurality of injection holes LH for injecting gas through the second plate LP, and may uniformly inject the reaction gas onto the substrate W through the plurality of injection holes LH. The shower head 100 may be arranged above the inner space 301 of the process chamber 302 to face the substrate support unit 200. A diameter of the shower head 100 may be greater than a diameter of the substrate support unit 200. Alternatively, the diameter of the shower head 100 may be greater than a diameter of the substrate W, but less than the diameter of the substrate support unit 200.

The substrate support unit 200 may be provided in the inner space 301. The substrate support unit 200 may include a chuck body 210, a cooling plate 220, and a support pillar 230 supporting the same. The substrate support unit 200 may fix the substrate W at a predetermined position. The chuck body 210 may include a chuck electrode 211, a heater 212, and a plasma electrode 213.

The chuck body 210 may have a cylindrical shape. The chuck body 210 may include ceramic or the like, but is not limited thereto. The substrate W may be arranged on a top surface of the chuck body 210. Although not shown separately, a focus ring and/or an edge ring may surround the chuck body 210.

The chuck electrode 211 may be located in the chuck body 210. The chuck electrode 211 may be positioned above the plasma electrode 213. DC power may be applied to the chuck electrode 211. More specifically, the DC power generator 321 may be electrically connected to the chuck electrode 211 through a first wiring 322, and the DC power generator 321 may apply DC power to the chuck electrode 211. The substrate W on the chuck body 210 may be fixed at a predetermined position by DC power applied to the chuck electrode 211 (e.g., an electrostatic force may fix the substrate W on the chuck body 210). The chuck electrode 211 may include aluminum (Al) or the like, but is not limited thereto.

The plasma electrode 213 may be located in the chuck body 210. The plasma electrode 213 may include aluminum (Al) or the like. The plasma electrode 213 may have a disk shape, but is not limited thereto. RF power may be applied to the plasma electrode 213. For example, the RF power generator 331 may be electrically connected to the plasma electrode 213 through a second wiring 332, and the RF power generator 331 may apply RF power to the plasma electrode 213 through the second wiring 332. Plasma in the inner space 301 may be controlled by RF power applied to the plasma electrode 213. The first wiring 322 and the second wiring 332 may extend inside the support pillar 230 to be connected to the chuck electrode 211 and the plasma electrode 213, respectively.

The heater 212 may be located in the chuck body 210. The heater 212 may be positioned between the chuck electrode 211 and the plasma electrode 213. The heater 212 may include a heat wire. For example, the heater 212 may include a heat wire forming a concentric circle. The heater 212 may generate heat to dissipate heat to the surroundings. Accordingly, the temperature of the chuck body 210 or the like may be increased by the heater 212.

The cooling plate 220 may be located below the chuck body 210. For example, the chuck body 210 may be positioned on the cooling plate 220. The cooling plate 220 may provide cooling holes 221. Cooling water may flow through the cooling holes 221. The cooling water in the cooling holes 221 may absorb heat from the cooling plate 220. The cooling plate 220 may be used for temperature control, such as preventing the temperature of the chuck body 210 from excessively increasing.

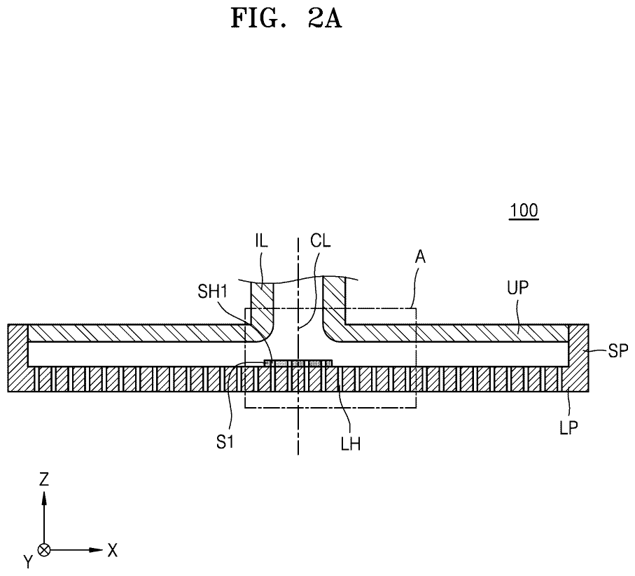

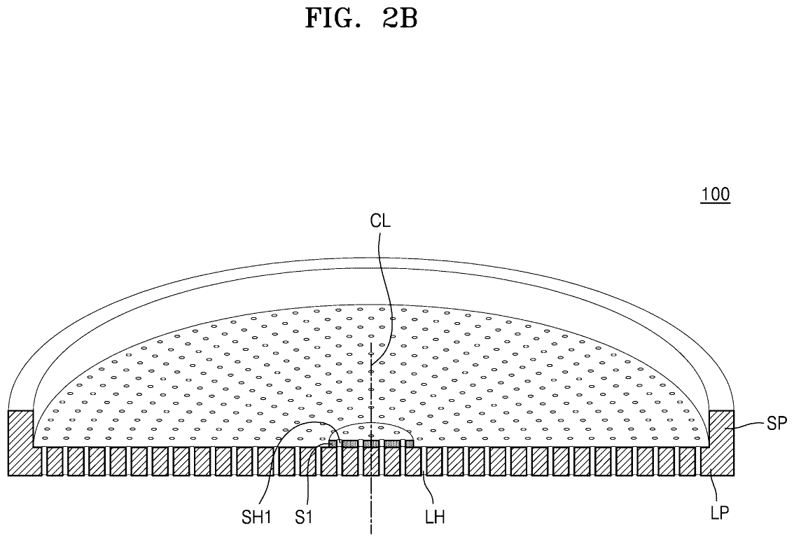

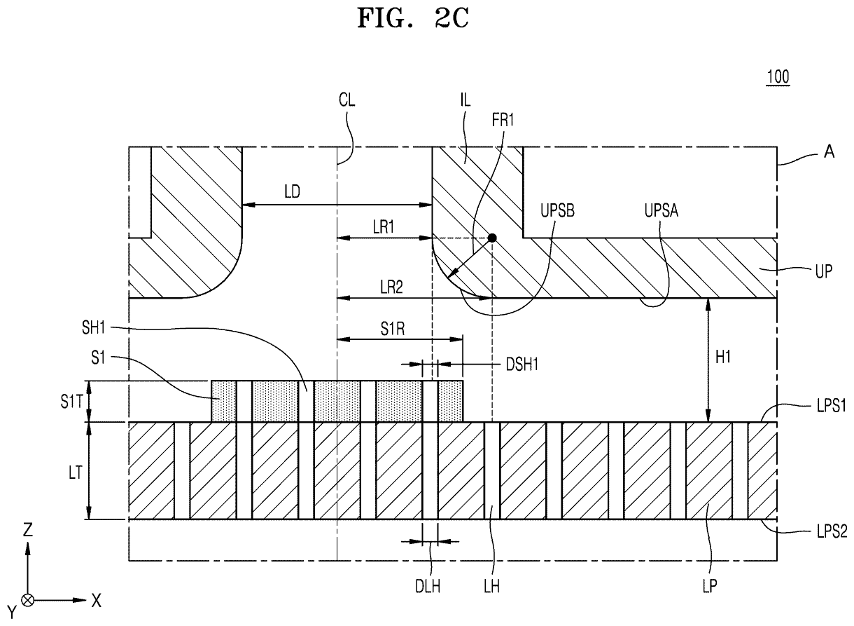

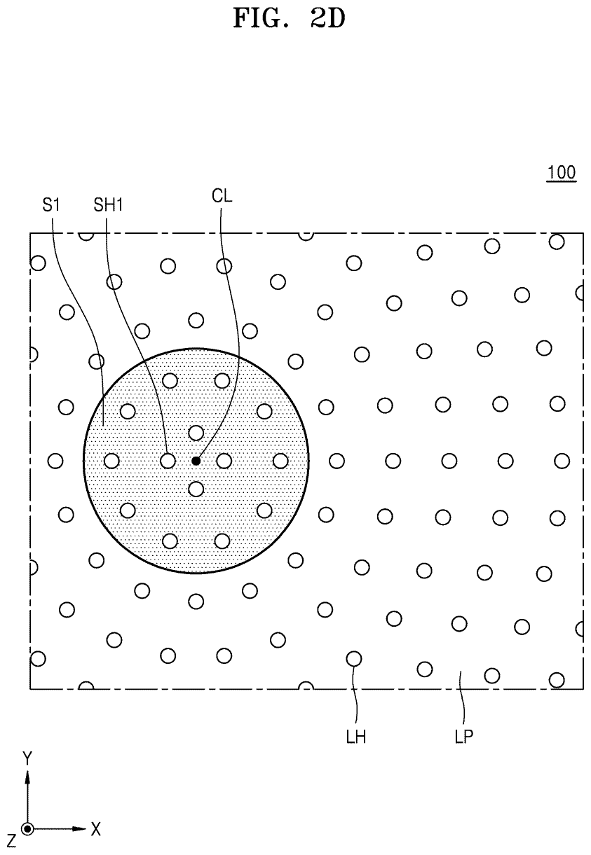

FIG. 2A is a cross-sectional view of the shower head 100 according to embodiments. FIG. 2B is a cross-sectional perspective view of the shower head 100 according to embodiments. FIG. 2C is an enlarged cross-sectional view of a portion of the shower head 100 according to embodiments. For example, FIG. 2C may be an enlarged cross-sectional view of portion A of FIG. 2A. FIG. 2D is an enlarged plan view of a portion of the shower head 100 according to embodiments.

Referring to FIGS. 2A to 2D, as described above, the shower head 100 may include the first plate UP, the second plate LP, the side plate SP extending from a side of the first plate UP to be coupled to the second plate LP, the gas inlet pipe IL connected to a central portion of the first plate UP to communicate with a gas inlet port 314, and the first step plate S1. In the present description, the first plate UP may be referred to as an upper plate, and the second plate LP may be referred to as a lower plate.

The first step plate S1 and the second plate LP may be separate components, wherein the first step plate S1 may be joined to the second plate LP via welding or fittings. Alternatively, the first step plate S1 and the second plate LP may be provided integrally in which a single body is formed to have the features of the first step plate S1 and the second plate LP.

The gas inlet pipe IL may be connected to a central portion of the first plate UP and internal passage of the gas inlet pipe may align with an opening in the first plate UP such that a fluid may flow from the inlet pipe through the first plate UP. A first fillet FR1 may be provided inside a portion where the gas inlet pipe IL and the first plate UP are connected to each other. The first fillet FR1 may include a fillet curved surface UPSB provided at a portion where a first surface UPSA of the first plate UP and the inner wall of the gas inlet pipe IL extend and meet each other. The first fillet FR1 may be provided to facilitate the flow of high-pressure gas flowing from the gas inlet pipe IL and improve the mechanical durability of the shower head 100. A radius of curvature of the first fillet FR1 may be, for example, equal to or less than a thickness of the gas inlet pipe IL. Alternatively, a radius of curvature of the first fillet FR1 may be equal to or less than a thickness of the first plate UP. For example, a radius of curvature of the first fillet FR1 may be in a range of about 2 mm to about 10 mm.

The first surface UPSA of the first plate UP may face the second surface LPS1 of the second plate LP. The first surface UPSA of the first plate UP may have a planar circular shape. The second surface LPS1 of the second plate LP may have a planar circular shape. The first surface UPSA of the first plate UP and the second surface LPS1 of the second plate LP may be parallel to each other. A first height H1, which is a vertical length by which the first surface UPSA of the first plate UP and the second surface LPS1 of the second plate LP are spaced apart from each other, may be in a range of, for example, about 8 mm to about 20 mm.

A plurality of injection holes LH may be provided in the second plate LP. Each of the plurality of injection holes LH may penetrate through the second plate LP in a thickness direction. For example, the plurality of injection holes LH may be holes extending from the second surface LPS1 to a third surface LPS2 of the second plate LP. The third surface LPS2 of the second plate LP is opposite to the second surface LPS1 of the second plate LP, and the third surface LPS2 of the second plate LP may face the substrate W when the substrate processing apparatus 1 is in use. A plurality of pillars may be provided between the first plate UP and the second plate LP in addition to the side plate SP to support the first plate UP and the second plate LP. The plurality of pillars may be connected to the first surface UPSA of the first plate UP and the second surface LPS1 of the second plate LP. The plurality of pillars are not shown in the example of FIGS. 2A to 2D.

The plurality of injection holes LH may extend in the thickness direction of the second plate LP such that the inside of the shower head 100 and the inner space 301 of the process chamber 302 may communicate with each other through the plurality of injection holes LH. The plurality of injection holes LH may have a generally uniform distribution density and may be provided in the second plate LP. The generally uniform distribution density serves to inject the gas onto the substrate W generally uniformly. The injection hole diameters DLH may be the same as one another in at least a portion of the plurality of injection holes LH. Alternatively, the injection hole diameters DLH of the plurality of injection holes LH may all be the same as one another for all of the plurality of injection holes LH.

A first step plate S1 may be provided on the second plate LP. The first step plate S1 may be provided on the second surface LPS1 of the second plate LP. The bottom surface of the first step plate S1 may be in contact with the second surface LPS1 of the second plate LP. The bottom surface of the first step plate S1 may face the second surface LPS1 of the second plate LP, and the top surface of the first step plate S1 may be a surface opposite to the bottom surface of the first step plate S1.

The second surface LPS1 of the second plate LP and the bottom surface of the first step plate S1 may be parallel to each other. The bottom surface of the first step plate S1 may be parallel to the top surface of the first step plate S1. Accordingly, the first surface UPSA of the first plate UP, the second surface LPS1 of the second plate LP, the top surface and the bottom surface of the first step plate S1 may all be parallel to each other. The first step plate S1 may have a flat plate shape having a constant thickness. As shown in FIG. 2D, the first step plate S1 may have a circular shape when viewed in a plan view.

As shown in FIG. 2D, a center of the first step plate S1 and a center of the second plate LP may coincide such that the first step plate S1 and the second plate LP are concentric circles when viewed in a plan view. A virtual first center line CL may pass through the center of the first step plate S1 with the center of the second plate LP. The first center line CL1 may be perpendicular to the second surface LPS1 of the second plate LP. The first center line CL1 may be perpendicular to each of the top surface and the bottom surface of the first step plate S1.

The first center line CL1 may also coincide with a center of the inner wall of the gas inlet pipe IL. For example, a cross-sectional shape of the inner wall of the gas inlet pipe IL when viewed in a plan view may be circular. The center of a cross-sectional shape of the inner wall of the gas inlet pipe IL when viewed in a plan view may coincide with the center of the first step plate S1 and the center of the second plate LP when viewed in a plan view. The coinciding centers serve to uniformly inject gas from the shower head 100.

A plurality of first step holes SH1 may be included in the first step plate S1. The plurality of first step holes SH1 may be provided through the first step plate S1. The plurality of first step holes SH1 may penetrate through the first step plate S1 in the thickness direction of the first step plate S1.

The first step hole diameters DSH1 of the plurality of first step holes SH1 may all be the same. The first step hole diameters DSH1 of the plurality of first step holes SH1 may be the same as the injection hole diameters DLH of the plurality of injection holes LH of the second plate LP, respectively. For example, the first step hole diameters DSH1 may be in a range of 0.5 mm to 1.5 mm. Likewise, the injection hole diameters DLH of the plurality of injection holes LH of the second plate LP may be in a range of about 0.5 mm to about 1.5 mm, for example. The numerical values for the first step hole diameters DSH1 and the diameter of each of the plurality of injection holes LH are examples and embodiments are not limited thereto.

The plurality of first step holes SH1 of the first step plate S1 may correspond to the plurality of injection holes LH of the second plate LP, respectively. The plurality of first step holes SH1 of the first step plate S1 may correspond to the plurality of injection holes LH of the second plate LP, respectively, and the former may be aligned with the latter in a vertical direction. The plurality of first step holes SH1 of the first step plate S1 may correspond to at least some of the plurality of injection holes LH of the second plate LP, respectively, and the former may communicate with the latter.

The plurality of injection holes LH of the second plate LP may be correspondingly aligned with at least some of the plurality of first step holes SH1 of the first step plate S1 in a vertical direction to form respective extended holes. A first thickness S1T of the first step plate S1 may be the same as the extended length of each of the plurality of first step holes SH1. Likewise, a thickness LT of the second plate LP may be the same as the extended length of each of the plurality of injection holes LH. An extended length of each of the plurality of extended holes formed by aligning the plurality of first step holes SH1 and the plurality of injection holes LH corresponding to the plurality of first step holes SH1 in a vertical direction may be the sum of the first thickness S1T of the first step plate S1 and the thickness LT of the second plate LP. Therefore, the length of the extended hole where the first step plate S1 is located may be greater by the first thickness S1T than the length of the hole where the first step plate S1 is not located among the plurality of injection holes LH.

For example, the thickness LT of the second plate may be in a range of about 5 mm to about 20 mm, and the first thickness S1T may be in a range of about 1 mm to about 6 mm. Alternatively, the thickness LT of the second plate may be in a range of about 2 times to about 20 times the first thickness S1T. However, embodiments are not limited to these numerical examples.

The plurality of injection holes LH of the second plate LP may be provided in the second plate LP point-symmetrically with respect to the first center line CL. Since the plurality of first step holes SH1 and the plurality of injection holes LH corresponding to the plurality of first step holes SH1 are aligned in a vertical direction to each other, the plurality of first step holes SH1 of the first step plate S1 may be provided in the second plate LP point-symmetrically with respect to the first center line CL. The arrangement of the plurality of injection holes LH and the plurality of first step holes SH1 having a point symmetrical distribution is an example and does not limit embodiments.

The gas introduced through the gas inlet pipe IL may apply a greater pressure to the second plate LP at an area vertically below the gas inlet pipe IL and the second plate LP adjacent to the area vertically below the gas inlet pipe IL inside the shower head 100. For example, assuming that the pressure in the inner space adjacent to the side plate SP of the shower head 100 is 1 as a reference value, the pressure in the central portion of the shower head 100 (i.e., the portion where the first step plate (S1) is provided) may reach approximately about 1.1 to about 1.2. That is, when gas is injected through the plurality of injection holes LH of the second plate LP without the first step plate S1, the uneven gas injection may be performed due to the pressure difference described above.

The shower head 100 according to embodiments is provided with the first step plate S1 in contact with the second plate LP. Due to the first step plate S1, the degree of injection of gas having a greater pressure in the center may be adjusted dependent on the thickness of the first step plate S1. For example, the first thickness S1T of the first step plate S1 may be in a range of about 2 mm to about 6 mm.

The Hagen-Poiseuille equation is an equation that shows the relationship between the flow rate Q and the pressure difference ΔP, assuming that a viscous Newtonian fluid passes through a cylindrical tube in a fully developed laminar flow state. The Hagen-Poiseuille equation is the same as a first equation below.

$$Q = \frac{{π ( \frac{D}{2} )}^{4}}{8 μ L} \cdot Δ P \qquad [ First Equation ]$$

(where Q is the flow rate (volume flow rate), D is the diameter of the hole, L is the length of the tube, ΔP is the pressure difference between both ends of the tube, and is the viscosity of the fluid)

By modifying the first equation, the conductance C of the hole formed in a straight line when the fluid is a viscous regime may be calculated by a second equation.

$$C ∝ \frac{{D}^{4}}{L} \cdot Δ P \qquad [ Second Equation ]$$

(where D is the diameter of the hole, L is the length of the hole, and ΔP is the pressure difference between both ends of the hole)

The second equation indicates that the conductance is proportional to the fourth power of the diameter of the straight hole, inversely proportional to the length of the straight hole, and proportional to the pressure difference between both ends of the straight hole. By adjusting the D and L values of each hole so that the conductance values approximately match, the gas injected from the shower head 100 may be made uniform. For example, it may be assumed that the length of each of the plurality of first step holes SH1 of the first step plate S1 is 2 mm, and the length of each of the plurality of injection holes LH of the second plate LP is 10 mm. As described above, assuming that the pressure in the inner space adjacent to the side plate SP of the shower head 100 is 1 as a reference value, the pressure in the central portion of the shower head 100 (i.e., the portion where the first step plate (S1) is provided) may reach approximately 1.2. In this case, the extended length of each of the plurality of extended holes formed by aligning the plurality of first step holes SH1 and the plurality of injection holes LH corresponding to the plurality of first step holes SH1 is 12 mm.

With respect to the conductance value for the injection hole LH adjacent to the side plate SP, the ratio of the conductance values of the plurality of extended holes formed by aligning the plurality of first step holes SH1 and the plurality of injection holes LH corresponding to the plurality of first step holes SH1 in the center portion of the shower head 100 may be calculated. Since the plurality of extended holes and the injection hole LH have the same diameter, and the pressure ratio based on the injection hole LH adjacent to the side plate SP is 1.2 and the length ratio of the holes is 1.2, the injection hole LH adjacent to the side plate SP and the extended holes may have the same conductance value. Therefore, since the first step plate S1 in which the plurality of first step holes SH1 are formed is provided on the second plate LP, uniform gas injection may be performed in the shower head 100. The numerical examples described above are intended to help understanding of the embodiments and do not limit the embodiments.

The shower head 100 according to embodiments includes the first plate UP and the second plate LP and does not have a baffle provided in the inner space of the shower head 100 and includes the first step plate S1 provided in contact with the second plate LP or integrated with the second plate LP. In an operating environment in which the shower head 100 is exposed to high-pressure gas, since a pillar for connecting the first step plate S1 with the second plate LP or fixing the first step plate S1 to the second plate LP is unnecessary, mechanical durability of the shower head 100 may be improved. In addition, by adjusting the conductance of the injection hole through the first thickness S1T of the first step plate S1, the injection of the uniform gas required by the shower head 100 through the first step plate S1 may also be achieved as described above.

The durability of the shower head 100 may be improved through the shower head 100 including the first step plate S1 according to embodiments, and at the same time, the uniform gas injection required by the shower head 100 may be achieved, thereby improving the yield of the processing of the substrate W.

The first radius S1R of the first step plate S1 may be greater than half of the inner diameter LD of the inlet pipe, which is the diameter of the inner wall of the gas inlet pipe IL, and less than half of the radius of the second plate LP. For example, the first radius S1R of the first step plate S1 may be in a range of about 10 mm to about 20 mm.

In addition, the side surface of the first step plate S1 may overlap the first fillet FR1 in a vertical direction. A first connection portion radius LR1 may be defined based on the first center line CL1 at a point extending from the inner wall of the gas inlet pipe IL to the fillet curved surface UPSB and a second connection portion radius LR2 may be defined based on the first center line CL1 at a point extending from the first surface UPSA of the first plate UP to the fillet curved surface UPSB. The second connection portion radius LR2 is greater than the first connection portion radius LR1. The first radius S1R of the first step plate S1 may be a value in a range of the first connection portion radius LR1 to the second connection portion radius LR2.

For example, when the radius of curvature of the first fillet FR1 is 5 mm and the radius of the gas inlet pipe IL is 10 mm, the first connection portion radius LR1 may be 10 mm and the second connection portion radius LR2 may be 15 mm. Accordingly, the first radius S1R of the first step plate S1 may be in a range of about 10 mm to about 15 mm.

The radius of the first step plate S1, as measured in a plan view, is to allow the gas flowing from the gas inlet pipe IL to pass through the plurality of first step holes SH1 of the first step plate S1 without being directly injected through the injection holes LH. Accordingly, the gas in the center of the shower head 100, which has a relatively greater pressure than the gas far from the center, may be injected through the plurality of injection holes LH of the second plate LP through the plurality of first step holes SH1 of the first step plate S1.

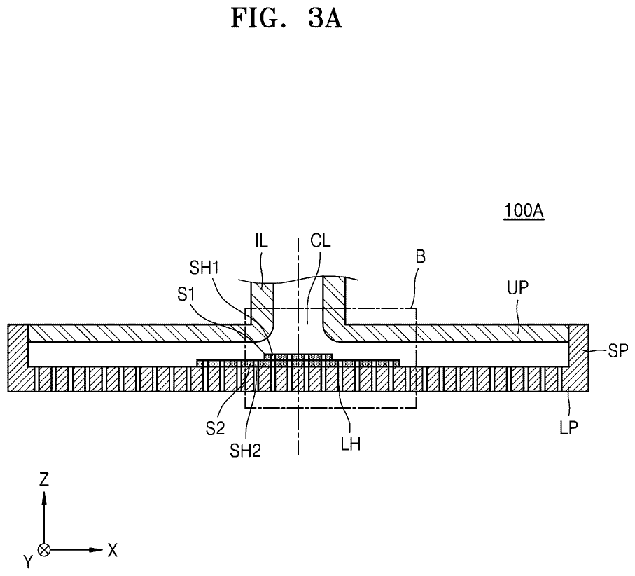

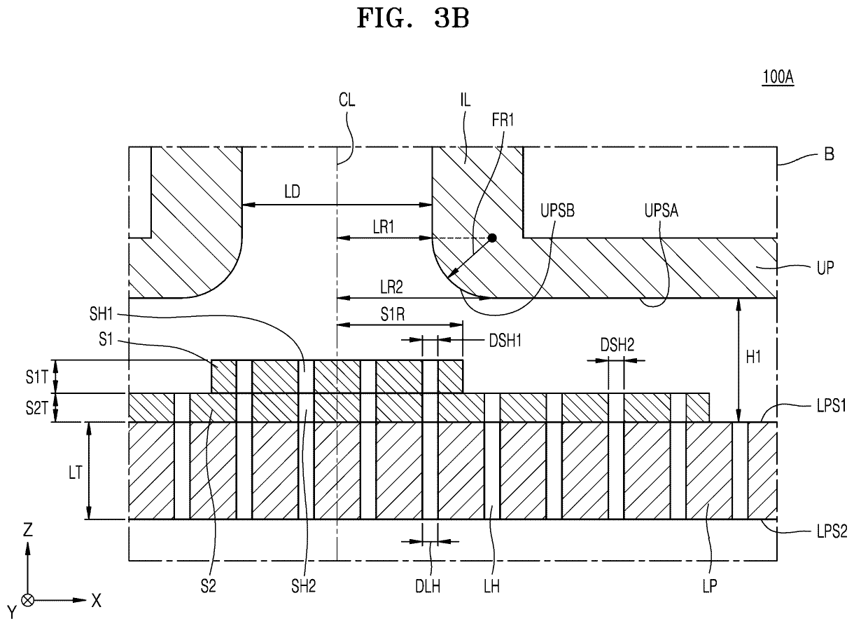

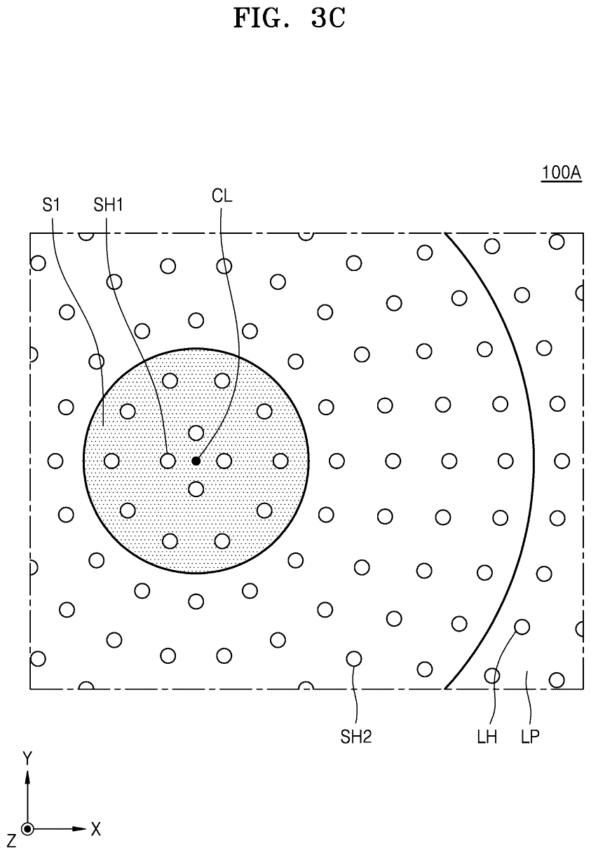

FIG. 3A is a cross-sectional view of a shower head 100A according to embodiments. FIG. 3B is an enlarged cross-sectional view of a portion of the shower head 100A according to embodiments. FIG. 3C is an enlarged plan view of the portion of the shower head 100A according to embodiments. More specifically, FIG. 3B is an enlarged cross-sectional view of portion B of FIG. 3A. Descriptions of features described previously may be omitted with the understanding that the description may be substantially the same as above.

Referring to FIGS. 3A to 3C, the shower head 100A may further include a second step plate S2. The second step plate S2 may be provided between the first step plate S1 and the second plate LP. The bottom surface of the second step plate S2 may face the second surface LPS1 of the second plate LP. The bottom surface of the second step plate S2 may be in contact with the second surface LPS1 of the second plate LP. The top surface of the second step plate S2 is a surface opposite to the bottom surface of the second step plate S2. The top surface of the second step plate S2 and the first step plate S1 may be in contact with each other.

The first step plate S1, the second step plate S2, and the second plate LP are separate configurations, and each of the first step plate S1, the second step plate S2, and the second plate LP may be coupled to each other through welding or fittings such as threaded fasteners. Alternatively, the second step plate S2 may be provided integrally with the second plate LP. Alternatively, the first step plate S1, the second step plate S2, and the second plate LP may all be provided integrally (e.g., formed of a single solid body).

The second step plate S2 may be concentric in a plan view with the first step plate S1, and the top surface and the bottom surface of the second step plate S2 may be perpendicular to the first center line CL, respectively. The top surface and the bottom surface of the second step plate S2 are parallel to each other, and the second step plate S2 may have a flat plate shape. When viewed in a plan view, the second step plate S2 may be circular.

The second radius S2R, which is the radius of the second step plate S2, may be defined with respect to the first center line CL1. The second radius S2R, which is the radius of the second step plate S2, may be greater than the first radius S1R of the first step plate S1 and may be equal to or less than half of the radius of the second plate LP. For example, the second radius S2R of the second step plate S2 may be in a range of about 20 mm to about 80 mm.

A second thickness S2T of the second step plate S2 may be equal to or less than the first thickness S1T of the first step plate S1. For example, the second thickness S2T may be in a range of about 1 times to about 0.2 times the first thickness S1T. Alternatively, the second thickness S2T may be, for example, in a range of about 0.5 mm to about 3 mm.

A plurality of second step holes SH2 may be provided in the second step plate S2. The plurality of second step holes SH2 may pass through the second step plate S2, respectively. The plurality of second step holes SH2 may be vertically aligned with at least some of the plurality of injection holes LH of the second plate LP. The plurality of second step holes SH2 may communicate with at least some of the plurality of injection holes LH of the second plate LP respectively corresponding to the plurality of second step holes SH2. In addition, the plurality of first step holes SH1 of the first step plate S1 correspond to at least some of the plurality of second step holes SH2 of the second step plate S2, and the plurality of first step holes SH1 and the plurality of second step holes SH2 corresponding to each other may be vertically aligned. Therefore, the first step holes SH1 may be vertically aligned with the corresponding second step holes SH2 and the corresponding injection holes LH, respectively.

The second step hole diameters DSH2 of the plurality of second step holes SH2 may all be the same. The second step hole diameters DSH2 of the plurality of second step holes SH2 may be the same as the injection hole diameters DLH of the plurality of injection holes LH of the second plate LP, respectively. For example, the second step hole diameters DSH2 may be in a range of 0.5 mm to 1.5 mm. Likewise, the injection hole diameters DLH of the plurality of injection holes LH of the second plate LP may be in a range of 0.5 mm to 1.5 mm, for example. Likewise, the first step hole diameters DSH1 of the plurality of first step holes SH1 may all be the same as the second step hole diameters DSH2 of the plurality of second step holes SH2. The first step hole diameters DSH1, the second step hole diameters DSH2, and the injection hole diameters DLH1 may all be the same. The numerical values for the diameters of each of the first step hole diameters DSH1, the second step hole diameters DSH2, and the plurality of injection holes LH are examples, and embodiments are not limited thereto.

The gas injected from the shower head 100A may be injected from the shower head 100A through three types of holes. The three types of holes may include a hole consisting of only the injection holes LH, holes formed by communicating the injection holes LH with the second step holes SH2 of the second step plate S2, and holes formed by communicating the injection holes LH, the second step holes SH2, and the first step holes SH1 of the first step plate S1 with each other.

The gas introduced into the inner space of the shower head 100A through the gas inlet pipe IL of the shower head 100A may exhibit a pressure gradient in which the relative pressure of the gas generally decreases the farther the distance from the first center line CL where the gas inlet pipe IL is located. The shower head 100A, according to an embodiment, is configured to eject gas through a length of a hole that gradually decreases with respect to the first center line CL1 in response to a pressure gradient in which the relative pressure of the gas generally decreases the farther the distance with respect to the first center line CL1. In the second equation, since the conductance is inversely proportional to the length of the hole and the conductance is proportional to the pressure difference between both ends of the hole, the conductance of the holes of the shower head 100A may be set to be constant by reducing the length of the hole as the distance from the first center line CL1 increases in response to the pressure gradient in which the relative pressure of the gas is generally reduced as the distance from the first center line CL1 increases.

Accordingly, the shower head 100A according to embodiments may adjust the conductance of the injection holes through the first thickness S1T of the first step plate S1 and the second thickness S2T of the second step plate S2, so that the required uniform injection of gas from the shower head 100 may be achieved. In addition, since a pillar for fixing the first step plate S1 to the second step plate S2 or connecting the first step plate S1 and the second step plate S2 to other components is unnecessary, the mechanical durability of the shower head 100A may be improved.

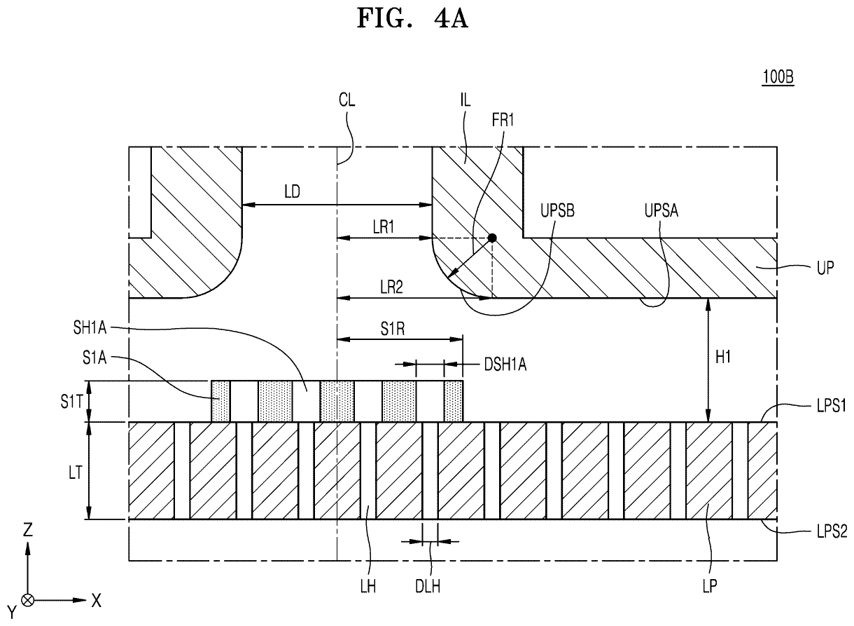

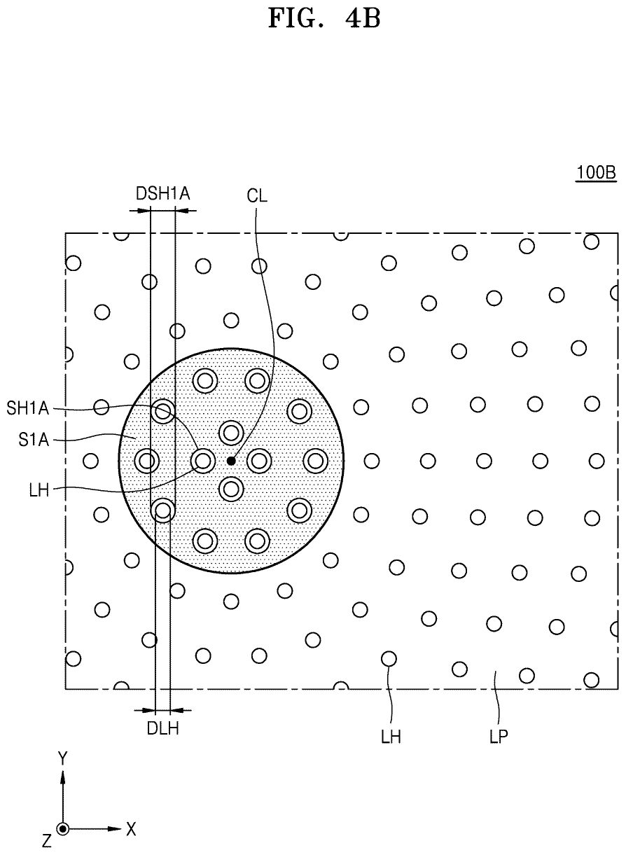

FIG. 4A is an enlarged cross-sectional view of a portion of a shower head 100B according to embodiments. FIG. 4B is an enlarged cross-sectional view of the portion of the shower head 100B according to embodiments. Descriptions that are not separately given may be substantially the same as those described above.

Referring to FIGS. 4A and 4B, a plurality of first step holes SH1A may be provided in a first step plate S1A. The first step hole diameters DS1A, which are the diameters of the plurality of first step holes SH1A, may be greater than the injection hole diameters DLH of the plurality of injection holes LH. For example, the first step hole diameters DS1A may be in a range of 0.7 mm to 1.7 mm. According to a change in the gradient of the gas relative pressure inside the shower head 100B, which is generated as a distance from the center increases, achieving uniform injection of gas may be limited with the first step holes SH1 having the same diameters as the injection holes LH of the first step plate S1 of FIGS. 2A to 2D described above. In this case, the plurality of first step holes SH1A having first step hole diameters DS1A greater than the injection hole diameters DLH may be provided in the first step plate S1A. By designing the first step hole diameters DSH1A of the plurality of first step holes SH1A according to process conditions, more uniform gas injection may be achieved in gas supply and gas injection through the shower head 100B.

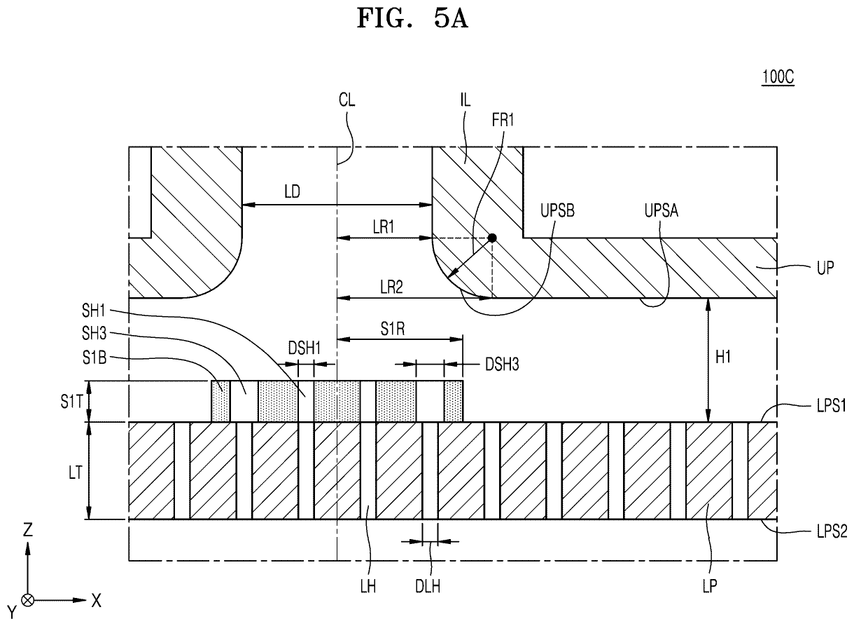

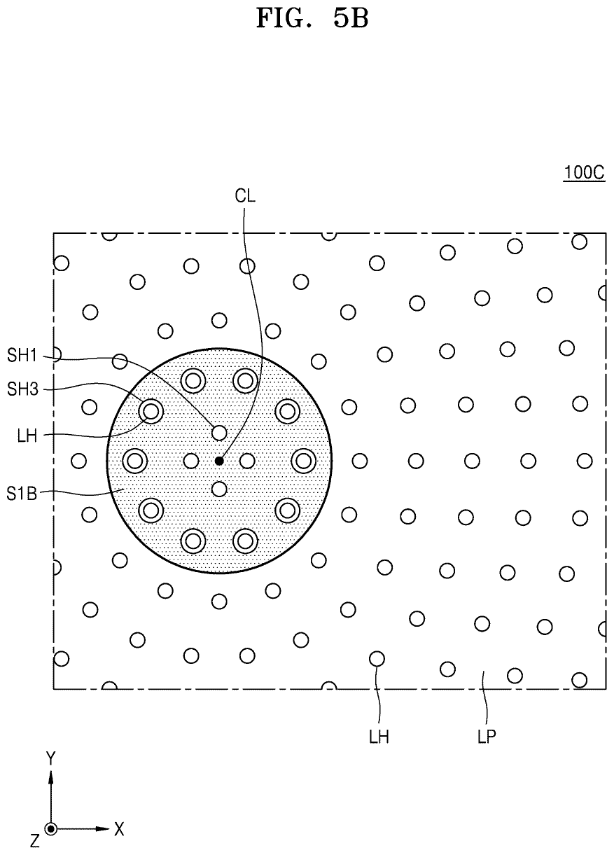

FIG. 5A is an enlarged cross-sectional view of a portion of a shower head 100C according to embodiments. FIG. 5B is an enlarged plan view of the portion of the shower head 100C according to embodiments. Descriptions that are not separately given may be substantially the same as those described above.

Referring to FIGS. 5A and 5B, a first step plate S1B may include a plurality of first step holes SH1 and a plurality of third step holes SH3. The plurality of first step holes SH1 and the plurality of third step holes SH3 may each penetrate the first step plate S1B in a vertical direction (thickness direction). The first step hole diameters DSH1, which are the diameters of the plurality of first step holes SH1, may be the same as the injection hole diameters DLH. The third step hole diameters DSH3, which are the diameters of the plurality of third step holes SH3, may be greater than the injection hole diameters DLH. That is, the third step hole diameters DSH3 may be greater than the first step hole diameters DSH1. For example, the third step hole diameters DSH3 may be in a range of 0.7 mm to 1.7 mm.

The plurality of third step holes SH3 may be vertically aligned with the plurality of injection holes LH. The plurality of third step holes SH3 may communicate with the plurality of injection holes LH respectively corresponding to the plurality of third step holes SH3. The plurality of third step holes SH3 may be vertically aligned with the plurality of injection holes LH corresponding to the plurality of third step holes SH3.

Step holes each having a greater diameter may be provided further away from the first center line CL1 of the first step plate S1B. For example, the plurality of third step holes SH3 may be arranged further distant from the first center line CL1 than the plurality of first step holes SH1. The shower head 100C according to embodiments may achieve more uniform gas injection by varying the diameter configuration of the plurality of step holes provided in the first step plate S1B.

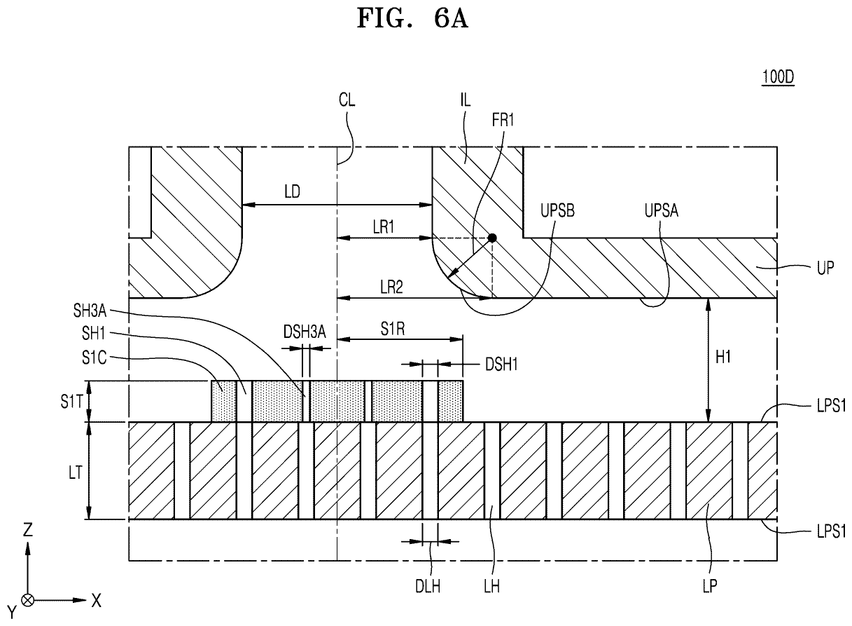

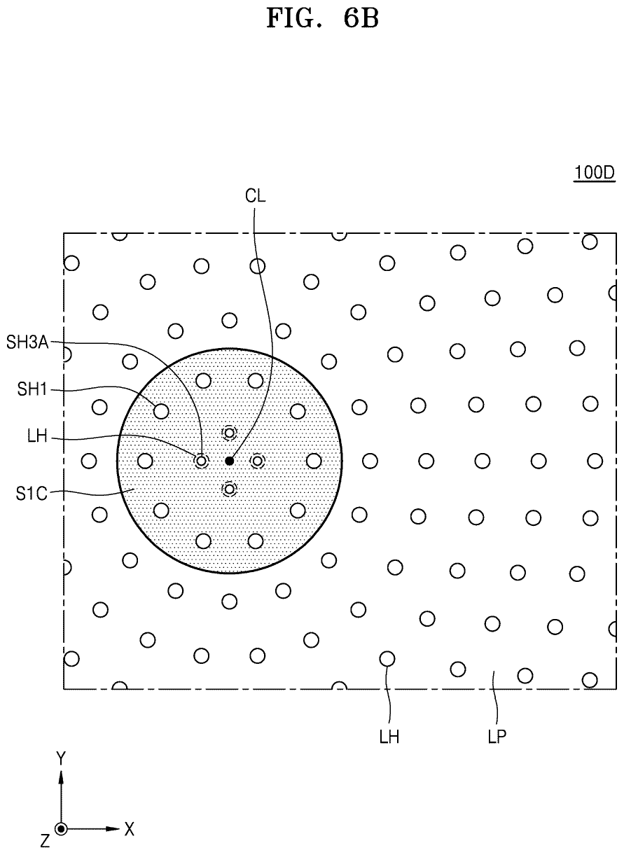

FIG. 6A is an enlarged cross-sectional view of a portion of a shower head 100D according to embodiments. FIG. 6B is an enlarged plan view of the portion of the shower head 100D according to embodiments. Descriptions that are not separately given may be substantially the same as those described above.

Referring to FIGS. 6A and 6B, a first step plate S1B may include a plurality of first step holes SH1 and a plurality of third step holes SH3A. The third step hole diameters DSH3A, which are the diameters of the plurality of third step holes SH3A, may be less than the first step hole diameters DSH1. The first step hole diameters DSH1 may be equal to the injection hole diameters DLH. For example, the third step hole diameters DSH3A may be in a range of 0.3 mm to 1.3 mm.

Step holes each having a greater diameter may be provided further away from the first center line CL1 of the first step plate S1C. For example, the plurality of first step holes SH1 may be arranged further distant from the first center line CL1 than the plurality of third step holes SH3A. The shower head 100D according to embodiments may achieve more uniform gas injection by varying the diameter configuration of the plurality of step holes provided in the first step plate S1C.

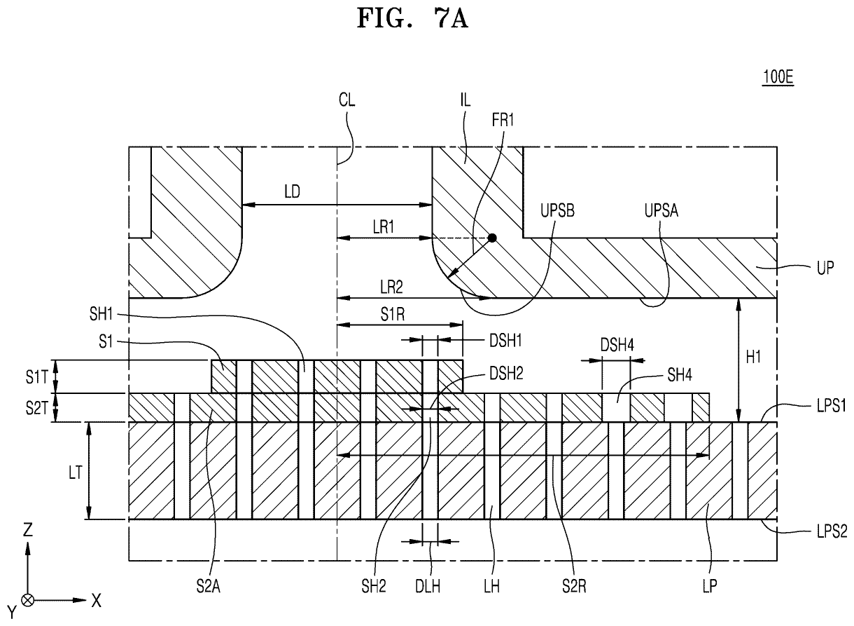

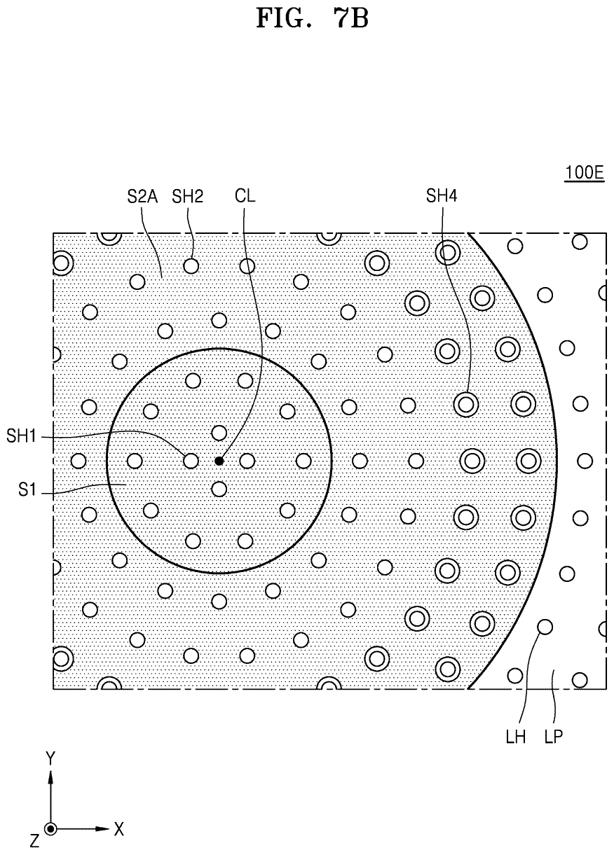

FIG. 7A is an enlarged cross-sectional view of a portion of a shower head 100E according to embodiments. FIG. 7B is an enlarged plan view of the portion of the shower head 100E according to embodiments. Descriptions that are not separately given may be substantially the same as those described above.

Referring to FIGS. 7A and 7B, a shower head 100E may include a first step plate S1 and a second step plate S2A. The second step plate S2A may include the plurality of second step holes SH2 and a plurality of fourth step holes SH4. Each of the plurality of second step holes SH2 and the plurality of fourth step holes SH4 may penetrate the second step plate S2A in the vertical direction (thickness direction).

The fourth step hole diameters DSH4, which are the diameters of the plurality of fourth step holes SH4, may be greater than the second step hole diameters DSH2. For example, the fourth step hole diameters DSH4 may be in a range of 0.7 mm to 1.7 mm. The injection hole diameters DLH, the first step hole diameters DSH1, and the second step hole diameters DSH2 may all be the same.

Step holes each having a greater diameter may be provided further away from the first center line CL1 of the second step plate S2A. For example, the plurality of fourth step holes SH4 may be arranged further distant from the first center line CL1 than the plurality of second step holes SH2.

The gas may be injected from the shower head 100E through four types of holes. The four types of holes may include a hole consisting of only the injection holes LH, holes formed by communicating the injection holes LH with the fourth step holes SH4 of the second step plate S2, holes formed by communicating the injection holes LH with the second step holes SH2 of the second step plate S2, and holes formed by communicating the injection holes LH, the second step holes SH2, and the first step holes SH1 of the first step plate S1 with each other.

The shower head 100E according to embodiments may achieve more uniform gas injection by varying the diameter configuration of the plurality of step holes provided in the second step plate S2A.

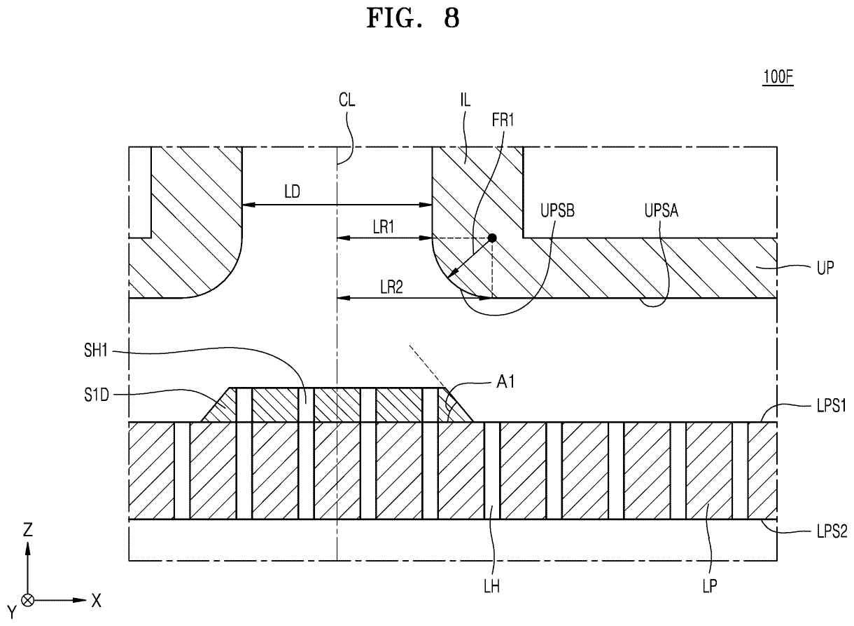

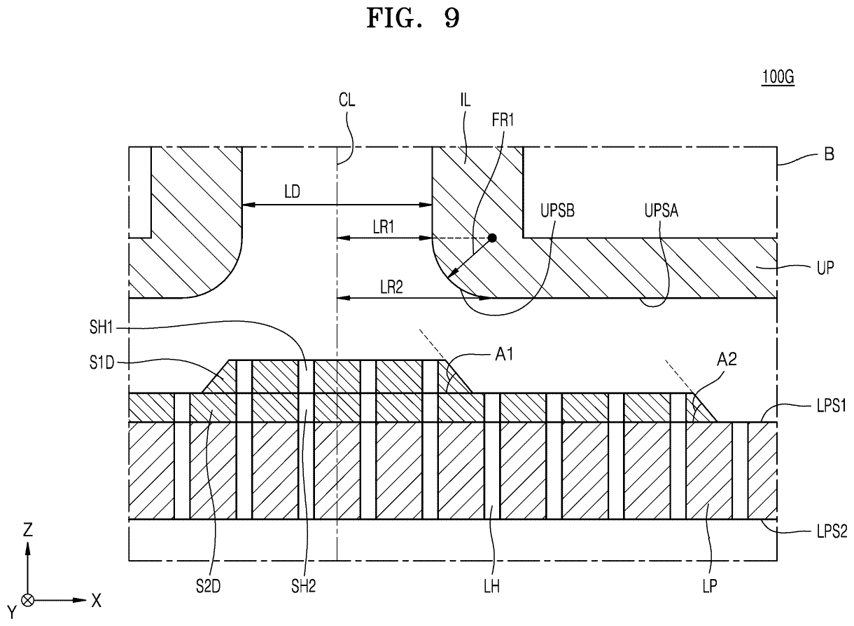

FIG. 8 is an enlarged cross-sectional view of a portion of a shower head 100F according to embodiments. FIG. 9 is an enlarged cross-sectional view of a portion of a shower head 100G according to embodiments. Descriptions that are not separately given may be substantially the same as those described above.

Referring to FIG. 8, the side surface of a first step plate SID may be formed at an acute angle with the second surface LPS1 of the second plate LP. The side surface of the first step plate SID may be formed obliquely with respect to the second surface LPS1, for example. For example, the first angle A1, which is an angle formed between the side surface of the first step plate SID and the second surface LPS1, may be in a range of 5° to 80°.

Since the side surface of the first step plate SID is inclined with respect to the second surface LPS1, a vortex generated due to the side surface of the first step plate S1D may be reduced in a plurality of injection holes LH provided adjacent to the side surface of the first step plate SID. Accordingly, the possibility of generating non-uniform gas injection of the gas injected from the plurality of injection holes LH adjacent to the side surface of the first step plate SID among the plurality of injection holes LH may be reduced. Accordingly, the shower head 100F according to embodiments may achieve more uniform gas injection.

Referring to FIG. 9, the side surface of the first step plate SID may form an acute angle with a top surface of a second step plate S2D, and the side surface of the second step plate S2D may form an acute angle with the second surface LPS1 of the second plate LP. The first angle A1, which is an angle formed by the side surface of the first step plate S1D and the top surface of the second step plate S2D, may be in a range of about 5° to about 80°, and the second angle A2, which is an angle formed by the side surface of the second step plate S2D with the second surface LPS1, may be in a range of about 5° to about 80°.

Since the side surface of the first step plate S1D and the side surface of the second step plate S2D are inclined, vortexes generated in the plurality of second step holes SH2 provided adjacent to the side surface of the first step plate S1D and the plurality of injection holes LH provided adjacent to the side surface of the second step plate S2D may be reduced. Accordingly, the shower head 100G according to embodiments may achieve more uniform gas injection.

While the inventive concept has been particularly shown and described with reference to embodiments thereof, it will be understood that various changes in form and details may be made therein without departing from the spirit and scope of the following claims.

What is claimed is:

1. A gas shower head comprising:
a first plate having a first surface facing a first direction;
an inlet at a center of the first plate;
a second plate having a second surface facing the first surface of the first plate; and
a first step plate provided on the second surface of the second plate, wherein
the first surface is parallel to the second surface,
the second plate includes a plurality of injection holes, the plurality of injection holes penetrate through the second plate,
the first step plate includes a plurality of first step holes, the plurality of first step holes penetrate through the first step plate, and
each first step hole of the plurality of first step holes is aligned in the first direction with a corresponding injection hole of the plurality of injection holes.

2. The gas shower head of claim 1, wherein the first step plate is in contact with the second surface of the second plate.

3. The gas shower head of claim 1, wherein a diameter of each of the plurality of first step holes is same as a diameter of a corresponding injection of the plurality of injection holes.

4. The gas shower head of claim 1, wherein
a first fillet is provided at a portion where an inner wall of the inlet and the first surface of the first plate intersect,
the first fillet includes a fillet curved surface extending between the inner wall of the inlet and the first surface, and
the fillet curved surface overlaps the circumference of the first step plate in the first direction.

5. The gas shower head of claim 1, wherein a shape of a cross section of the inlet and a planar shape of the first step plate are each circular.

6. The gas shower head of claim 1, wherein each of the second plate and the first step plate has a circular planar shape and the center of the circular planar shape of each of the first step plate and the second plate is located on a virtual first center line.

7. The gas shower head of claim 1, wherein the first step plate and the second plate are integrally formed.

8. The gas shower head of claim 1, wherein
the diameter of each injection hole of the plurality of injection holes is same, and
the diameter of at least some first step holes of the plurality of first step holes is greater than the diameter of each injection hole of the plurality of injection holes.

9. The gas shower head of claim 1, wherein:
the first step plate further includes a plurality of third step holes;
each third step hole of the plurality of third step holes penetrates through the first step plate;
each third step hole of the plurality of third step holes are aligned in a first direction with a corresponding injection hole of the plurality of injection holes of the second plate;
the diameter of each third step hole of the plurality of third step holes is greater than the diameter of each first step hole of the plurality of first step holes, respectively; and
each third step hole of the plurality of third step holes is provided farther away from a first center line than the plurality of first step holes, and the first center line is defined by a virtual line that passes through a center of the first step plate and is perpendicular to the second surface of the second plate.

10. The gas shower head of claim 1, wherein a thickness of the second plate is within a range of 2 times to 20 times a thickness of the first step plate.

11. The gas shower head of claim 1, wherein:
a thickness of the second plate is in a range of 5 mm to 20 mm; and
a thickness of the first step plate is in a range of 1 mm to 8 mm.

12. The gas shower head of claim 1, further comprising a second step plate provided between the first step plate and the second plate, wherein:
the second step plate is provided with a plurality of second step holes;
the plurality of second step holes penetrate through the second step plate;
each first step hole of the plurality of first step holes is aligned in the first direction with a corresponding second step hole of the plurality of second step holes,
each second step hole of the plurality of second step holes is aligned in the first direction with a corresponding injection hole of the plurality of injection holes,
the second step plate is provided on and in contact with the second surface of the second plate, and
the first step plate is provided in contact with a surface of the second step plate.

13. The gas shower head of claim 12, wherein the thickness of the first step plate is equal to or greater than the thickness of the second step plate.

14. The gas shower head of claim 12, wherein the first step plate, the second step plate, and the second plate are integrally formed.

15. The gas shower head of claim 12, wherein:
the second step plate is provided with a plurality of fourth step holes;
each fourth step hole of the plurality of fourth step holes penetrates through the second step plate;
each fourth step hole of the plurality of fourth step holes is aligned in the first direction with a corresponding injection hole of the plurality of injection holes of the second plate; and
the diameter of each fourth step hole of the plurality of fourth step holes is greater than the diameter of each second step hole of the plurality of second step holes.

16. The gas shower head of claim 15, wherein each fourth step hole of the plurality of fourth step holes is provided farther away from a first center line than the plurality of second plate step holes, and the first center line is defined by a virtual line that passes through a center of the first step plate and is perpendicular to the second surface of the second plate.

17. A gas shower head comprising:
a first plate having a first surface facing a first direction;
an inlet at a center of the first plate;
a second plate having a second surface facing the first surface of the first plate; and
a first step plate provided on the second surface and having a third surface facing the first surface of the first plate and a fourth surface facing the second surface of the second plate,
wherein:
the second plate includes a plurality of injection holes, the plurality of injection holes penetrate through the second plate, and each injection hole of the plurality of injection holes has the same diameter;
the first step plate includes a plurality of first step holes, the plurality of first step holes penetrate through the first step plate, and
each first step hole of the plurality of first step holes is aligned in a first direction with a corresponding injection hole of the plurality of injection holes;
the first surface of the first plate, the second surface of the second plate, the third surface of the first step plate, and the fourth surface of the first step plate are all parallel to each other; and
a center of the first step plate, a center of the second plate, and a center of the inlet are all located on a virtual first center line extending in the first direction.

18. The gas shower head of claim 17, wherein a first inclination angle, which is an angle formed between a side surface of the first step plate and the second surface of the second plate, is in a range of 5° to 80°.

19. The gas shower head of claim 17, wherein
a diameter of the first step plate is greater than the diameter of the inlet, and
the diameter of the first step plate is less than ½ of the diameter of the second plate.

20. A substrate processing apparatus comprising:
a process chamber having an inner space;
a gas shower head provided in one side of the inner space of the process chamber;
a gas supply unit connected to the gas shower head to provide gas;
and a substrate support unit provided in the inner space of the process chamber, and configured to support a substrate,
wherein:
the gas shower head includes a first plate having a first surface, an inlet connected to the center of the first plate, a second plate having a second surface facing the first surface of the first plate, and a first step plate provided on the second surface of the second plate and having a an upper surface facing the first surface of the first plate and a lower surface facing the second surface of the second plate;
the first surface, the second surface, the upper surface of the first step plate, and the lower surface of the first step plate are parallel to each other;
the second plate includes a plurality of injection holes, the plurality of injection holes penetrate through the second plate, the first step plate includes a plurality of first step holes, and the plurality of first step holes penetrate through the first step plate;
each first step hole of the plurality of first step holes are aligned in a vertical direction with a corresponding injection hole of the plurality of injection holes;
the lower surface of the first step plate is in contact with the second surface of the second plate;
the diameter of the first step plate is greater than the diameter of the inlet;
a first fillet is provided at the intersection the inlet and the first surface of the first plate, the first fillet includes a fillet curved surface extending between the inlet and the first surface; and
the substrate support unit includes a chuck electrode, a heater, and a plasma electrode inside the substrate support unit.
